(19) United States
(12) Patent Application Publication
(10) Pub. No.: US 2025/0113741 A1
(43) Pub. Date: Apr. 3, 2025

(54) MAGNETORESISTIVE DEVICES AND METHODS OF MANUFACTURING THE SAME

(71) Applicant: Everspin Technologies, Inc., Chandler, AZ (US)

(72) Inventors: Sumio IKEGAWA, Phoenix, AZ (US); Kerry Joseph NAGEL, Scottsdale, AZ (US); Raj KUMAR, Chandler, AZ (US); Syed M. ALAM, Austin, TX (US)

(73) Assignee: Everspin Technologies, Inc., Chandler, AZ (US)

(21) Appl. No.: 18/897,637

(22) Filed: Sep. 26, 2024

Related U.S. Application Data
(60) Provisional application No. 63/586,315, filed on Sep. 28, 2023.

(51) Int. Cl. H10N 50/10; H10B 61/00; H10N 50/01

(52) U.S. Cl. CPC H10N 50/10; H10B 61/22; H10N 50/01

(57) ABSTRACT

A magnetoresistive random-access memory (MRAM) device includes a magnetoresistive tunnel junction (MTJ) device, an electrode, and a coupling layer. The MTJ device includes a free layer, a fixed layer, and a tunnel barrier layer positioned between the free layer and the fixed layer. The coupling layer is positioned between and coupling the electrode and the MTJ device. The coupling layer includes spin Hall channel (SHC) material. The free layer, the fixed layer, and the tunnel barrier layer are stacked in a first direction to form MTJ device. The electrode is nonaligned with the MTJ device such that the electrode is spaced away from the MTJ in a second direction that is different from the first direction.

### CROSS-REFERENCE TO RELATED APPLICATION

This application claims benefit to U.S. Provisional Patent Application No. 63/586,315, filed Sep. 28, 2023, the entire contents of which are incorporated herein by reference.

### TECHNICAL FIELD

Embodiments of the present disclosure relate to, among other things, magnetoresistive devices and methods of manufacturing the same. In some aspects, embodiments of the present disclosure relate to, among other things, magnetoresistive devices and methods of manufacturing magnetoresistive devices, for example, for a magnetoresistive random access memory.

### INTRODUCTION

In general, a memory system may include a memory device for storing data and a host (or controller) for controlling operations of the memory device. Memory devices may be classified into volatile memory (such as, e.g., dynamic random-access memory (DRAM), static random-access memory (SRAM), etc.) and non-volatile memory (such as, e.g., electrically erasable programmable read-only memory (EEPROM), ferroelectric random-access memory (FRAM), phase-change memory (PRAM), magnetoresistive random-access memory (MRAM), resistive random-access memory (RRAM/ReRAM), flash memory, etc.). For example, the memory system may include a plurality or array of MRAM devices, and one or more of the MRAM devices may be programmed or written via one or more write currents, for example, to set a direction of the free region or layer of the MRAM device. In some aspects, a large amplitude or duration of write current may be needed to set or write the MRAM device, which may decrease the endurance cycles, decrease the lifetime of the MRAM device, or otherwise negatively affect the MRAM device or the memory device as a whole.

### BRIEF DESCRIPTION OF THE DRAWINGS

In the course of the detailed description that follows, reference will be made to the appended drawings. The drawings show different aspects of the present disclosure and, where appropriate, reference numerals illustrating like structures, components, materials, and/or elements in different figures are labeled similarly. It is understood that various combinations of the structures, components, and/or elements, other than those specifically shown, are contemplated and are within the scope of the present disclosure.

Moreover, there are many embodiments of the present disclosure described and illustrated herein. The present disclosure is neither limited to any single aspect nor embodiment thereof, nor to any combinations and/or permutations of such aspects and/or embodiments. Moreover, each of the aspects of the present disclosure, and/or embodiments thereof, may be employed alone or in combination with one or more of the other aspects of the present disclosure and/or embodiments thereof. For the sake of brevity, certain permutations and combinations are not discussed and/or illustrated separately herein; however, all permutations and combinations are considered to fall within the scope of the present inventions.

FIG. 1 depicts a functional block diagram of an exemplary MRAM device, according to aspects of this disclosure.

FIGS. 2A-2D each depict a functional block diagram of various exemplary MRAM devices, according to aspects of this disclosure.

FIGS. 3A and 3B each depict a functional block diagram of an array of a plurality of MRAM devices coupled via a source line and a plurality of bit lines, according to aspects of this disclosure.

FIGS. 4A-4G depict a plurality of steps or stages of a formation procedure to form a MRAM device, according to aspects of this disclosure.

FIGS. 5A-5F illustrate graphs of various aspects of exemplary MRAM devices and responses during a write pulse.

FIG. 6 is a schematic diagram of an exemplary magnetoresistive memory stack electrically connected to a select device, for example, an access transistor, in a magnetoresistive memory cell configuration, according to aspects of this disclosure.

FIGS. 7A and 7B are schematic block diagrams of integrated circuits including a discrete memory device and an embedded memory device, respectively, each including an MRAM (which, in one embodiment is representative of one or more arrays of MRAM having a plurality of magnetoresistive memory structures according to aspects of certain embodiments of this disclosure).

Again, there are many embodiments described and illustrated herein. The present disclosure is neither limited to any single aspect nor embodiment thereof, nor to any combinations and/or permutations of such aspects and/or embodiments. Each of the aspects of the present disclosure, and/or embodiments thereof, may be employed alone or in combination with one or more of the other aspects of the present disclosure and/or embodiments thereof. For the sake of brevity, many of those combinations and permutations are not discussed separately herein.

As used herein, the terms “comprises,” “comprising,” “has,” “having,” “includes,” “including,” or any other variation thereof, are intended to cover a non-exclusive inclusion, such that a process, method, article, or apparatus that comprises a list of elements does not include only those elements, but may include other elements not expressly listed or inherent to such process, method, article, or apparatus. The term “exemplary” is used in the sense of “example,” rather than “ideal.

### DETAILED DESCRIPTION

Detailed illustrative aspects are disclosed herein. However, specific structural and functional details disclosed herein are merely representative for purposes of describing example embodiments of the present disclosure. The present disclosure may be embodied in many alternate forms and should not be construed as limited to only the embodiments set forth herein. Further, the terminology used herein is for the purpose of describing particular embodiments only and is not intended to be limiting of exemplary embodiments described herein.

When the specification makes reference to “one embodiment” or to “an embodiment,” it is intended to mean that a particular feature, structure, characteristic, or function described in connection with the embodiment being discussed is included in at least one contemplated embodiment of the present disclosure. Thus, the appearance of the phrases, “in one embodiment” or “in an embodiment,” in different places in the specification does not constitute a plurality of references to a single embodiment of the present disclosure.

As used herein, the singular forms “a,” “an,” and “the” are intended to include the plural forms as well, unless the context clearly indicates otherwise. It also should be noted that in some alternative implementations, the features and/or steps described may occur out of the order depicted in the figures or discussed herein. For example, two steps or figures shown in succession may instead be executed substantially concurrently or may sometimes be executed in the reverse order, depending upon the functionality/acts involved. In some aspects, one or more described features or steps may be omitted altogether, or may be performed with an intermediate step therebetween, without departing from the scope of the embodiments described herein, depending upon the functionality/acts involved.

Further, the terms “first,” “second,” and the like, herein do not denote any order, quantity, or importance, but rather are used to distinguish one element from another. Similarly, terms of relative orientation, such as “top,” “bottom,” etc. are used with reference to the orientation of the structure illustrated in the figures being described. It should also be noted that all numeric values disclosed herein may have a variation of ±10% (unless a different variation is specified) from the disclosed numeric value. Further, all relative terms such as “about,” “substantially,” “approximately,” etc. are used to indicate a possible variation of ±10% (unless noted otherwise or another variation is specified).

In some aspects, this disclosure is directed to devices and implementations of storage and/or processing devices, including, e.g., non-volatile or “permanent” memory (e.g., Flash, MRAMs, or ReRAMs). The devices and implementations include storage and/or processing devices with integrated controllers or control circuity, for example, for field programmable gate array (FPGA) system(s). The devices and implementations may help to reduce the necessary current (e.g., amplitude, duration, etc.), improve processing speed, or otherwise improve lifetime or performance.

There are many inventions described and illustrated herein, as well as many aspects and embodiments of those inventions. In one aspect, the present disclosure relates to magnetoresistive structures (for example, part of a magnetoresistive memory device, magnetoresistive sensor/transducer device, etc.) and methods of manufacturing the described magnetoresistive structures. For example, the disclosed structures may be related to magnetoresistive random access memory (MRAM) devices, magnetoresistive sensor/transducer devices, etc. To describe aspects of the disclosed devices and methods, exemplary magnetoresistive stack configurations are described. However, these are only exemplary. The disclosed devices can have many other stack configurations, and the disclosed methods can be applied to manufacture magnetoresistive devices having various suitable magnetoresistive stacks.

A magnetoresistive stack used in a memory device (e.g., an MRAM device) includes at least one non-magnetic layer (for example, at least one dielectric layer or a non-magnetic yet electrically conductive layer) disposed between a fixed magnetic region (e.g., a fixed region) and a free magnetic region (e.g., a free region), each including one or more layers of ferromagnetic materials. Information may be stored in the magnetoresistive stack by switching, programming, and/or controlling the direction of magnetization vectors in the magnetic layer(s) of the free region. The direction of the magnetization vectors of the free region may be switched and/or programmed (for example, through spin-transfer torque (STT)) by application of a write signal (e.g., one or more current pulses) through the magnetoresistive memory stack. In contrast, the magnetization vectors in the magnetic layers of a fixed region are magnetically fixed in a predetermined direction. The direction of the magnetization vectors of the free region can also be changed by spin-orbit torque (SOT) by application of write current through spin Hall channel material that is in contact with the free region. Here, the current through spin Hall channel material generates a spin current perpendicular to the current direction and perpendicular to the interface between the spin Hall channel material and the free region. Thus, the spin current is injected to the free region and exerts a torque on free region magnetization.

When the magnetization vectors of the free region adjacent to the non-magnetic layer are in the same direction as the magnetization vectors of the fixed region adjacent to the non-magnetic layer, the magnetoresistive memory stack has a first magnetic state. Conversely, when the magnetization vectors of the free region adjacent to the non-magnetic layer are opposite the direction of the magnetization vectors of the fixed region adjacent to the non-magnetic layer, the magnetoresistive memory stack has a second magnetic state. Together, the magnetic regions on either side of the non-magnetic layer form a magnetic tunnel junction (MTJ) when the non-magnetic layer is a dielectric material. The MTJ has different electrical resistances in the first and second magnetic states. For example, a resistance of the second magnetic state may be relatively higher than a resistance of the first magnetic state. The magnetic state of the magnetoresistive memory stack is determined or read based on the resistance of the stack in response to a read current applied, for example, through the magnetoresistive stack.

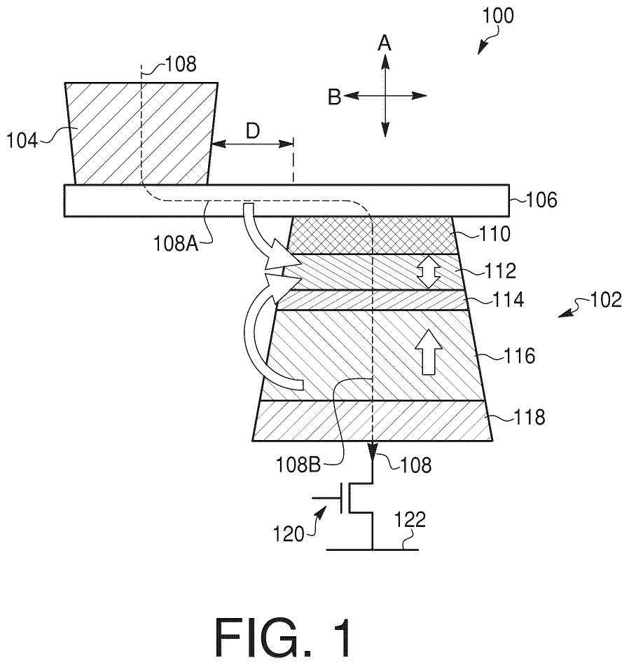

FIG. 1 depicts a functional block diagram of a magnetoresistive random-access memory (MRAM) device 100, for example, an STT-MRAM device. MRAM device 100 includes a magnetoresistive tunnel junction (MTJ) device 102 and an electrode 104, for example, with one or more layers of a material (e.g., spin Hall channel material) forming a coupling layer 106 between MTJ device 102 and electrode 104. Electrode 104 may be an electrode via. As shown in FIG. 1, MTJ device 102 and electrode 104 are not aligned, but are instead shifted or otherwise spaced away, offset, or nonaligned (e.g., horizontally) from each other by a distance D. For example, distance D may be approximately twice of a thickness of the coupling layer 106. In these aspects, electrode 104 is spaced away from or not aligned with a central axis or central through line by distance D. In some examples, MTJ device 102 includes a diameter (e.g., in direction B) of approximately 50 nm, and coupling layer 106 includes a thickness (e.g., in direction A) of approximately 5 nm. In this example, distance D may be approximately 10 nm to approximately 25 nm. For example, distance D may be greater than approximately two times the thickness of coupling layer 106. Alternatively or additionally, distance D may be equal to or greater than approximately 20% of the diameter of MTJ device 102 (e.g., D_{MTJ}), and distance D may be equal to or less than approximately 50% of the diameter of MTJ device 102 (e.g., 0.2 D_{MTJ} ≤D≤0.5 D_{MTJ}).

For example, as shown in FIG. 1, MTJ device 102 may include a first, vertical, or stacking direction A (e.g., defined by the central axis or central through line of MTJ device). As discussed in detail below, MTJ device 102 may include a plurality of layers or materials, and the layers or materials may be stacked or otherwise arranged along direction A. Additionally, electrode 104 is spaced away from or not aligned with MTJ device 102 in a direction non-parallel to direction A. For example, electrode 104 may be spaced away from, offset, or otherwise not aligned with MTJ device 102 in a direction B. Direction B may be perpendicular to direction A, or direction B may be otherwise non-parallel to direction A. In these aspects, the distance D that electrode 104 is spaced away from MTJ device 102 may be substantially in direction B.

Additionally, a write current 108 may flow through various portions of MTJ device 102, electrode 104, and the one or more layers of material forming coupling layer 106. For example, write current 108 may flow from an input to an output on opposing sides of MRAM device. At least a portion of the flow of write current 108 through coupling layer 106 may be perpendicular to the flow of write current 108 through at least portions of electrode 104 or MTJ device 102.

MTJ device 102 includes a plurality of layers. For example, as shown in FIG. 1, MTJ device 102 includes a first layer 110. First layer 110 may include a spin Hall channel material, for example, a spin Hall channel material with a higher resistance or resistivity than the spin Hall channel material forming coupling layer 106.

Next, MTJ device 102 includes a second layer 112. Second layer 112 may be a free layer, for example, a free magnetic region (e.g., a free or sense region), including one or more layers of ferromagnetic materials. For example, second layer 112 may include a first ferromagnetic material (e.g., a first patterned ferromagnetic material).

Furthermore, MTJ device 102 includes a third layer 114. Third layer 114 may be a tunnel barrier layer, for example, formed of a non-magnetic, insulating material. Third layer 114 may help to form a tunnel junction between layers or materials on opposing sides of third layer 114.

MTJ device 102 also includes a fourth layer 116. Fourth layer 116 may be a fixed layer, for example, a fixed magnetic region (e.g., a fixed or reference region), including one or more layers of ferromagnetic materials. For example, fourth layer 116 may include a second ferromagnetic material (e.g., a second patterned ferromagnetic material).

In these aspects, second layer 112, third layer 114, and fourth layer 116 may form a TMR element or cell. For example, second layer 112 has a magnetization direction that is free to rotate by applying a magnetic field, spin-transfer torque, or spin-orbit torque. Fourth layer 116 (reference layer) has a fixed reference magnetization direction that hardly rotates by a magnetic field, spin-transfer torque, or spin-orbit torque. If the magnetization directions of the two layers are parallel to each other, the electrical resistance of third layer 114 (e.g., the tunnel barrier) is relatively low. Conversely, when the magnetization directions are antiparallel, the resistance is relatively higher.

The TMR element cell formed by second layer 112, third layer 114, and fourth layer 116 therefore converts a magnetic field into electrical signal by changing the electrical resistance due to a changing angle of the magnetization direction of the magnetic free layer relative to the reference magnetization direction of the fixed layer in response to the field. The ferromagnetic layers (e.g., second layer 112 and fourth layer 116) may be formed from any suitable ferromagnetic material, such as Ni, Fe, Co, or their alloys. The insulating tunnel barrier (e.g., third layer 114) may be composed of insulator materials such as AlOx, MgOx, ZrOx, TiOx, HfOx, or any combinations thereof

In some aspects, MTJ device 102 includes a fifth layer 118. Fifth layer 118 may be a seed layer, for example, helping to couple MTJ to one or more other components, connections, etc. In some aspects, MTJ device 102 includes a central or main axis. For example, first layer 110, second layer 112, third layer 114, fourth layer 116, or fifth layer 118 may be stacked to define an axis of the MTJ device extending in a first direction (e.g., in direction A). As mentioned above, electrode 104 is spaced away, offset, or otherwise nonaligned with MTJ device 102, for example, in direction B.

MTJ device 102 may be electrically connected to one or more sense amplifiers, one or more write drivers, etc. For example, MTJ device 102 may be coupled to one or more transistors 120 and/or one or more bit lines 122, for example, for measurement of the resistance of the TMR element and/or for write current 108 to continue through the write circuit.

In these aspects, a portion (e.g., a horizontal portion) of electrode 104 is shifted or otherwise spaced apart from MTJ device 102, and electrode 104 and a free layer (e.g., second layer 112) of MTJ device 102 are connected (e.g., electrically connected) by spin Hall channel material. As shown in FIG. 1, two layers of spin Hall channel material (e.g., coupling and first layers 106 and 110) are positioned between the free layer of MTJ device 102 and electrode 104. Additionally, in some aspects, one layer or portion of the spin Hall channel material (e.g., first layer 110) includes a higher resistivity than the other layer or portion of spin Hall channel material (e.g., coupling layer 106).

Electrode 104 may be connected (e.g., electrically connected) to one or more inputs or outputs, for example, such that write current 108 may flow through MTJ device 102, electrode 104, and the one or more layers of material in coupling layer 106. Additionally, when write current 108 flows through coupling layer 106, write current 108 may form a first or horizontal component 108A of write current 108. Furthermore, because electrode 104 is spaced apart from MTJ device 102 by distance D, first component 108A of write current 108 may exert a torque on second layer 112. For example, first component 108A of write current 108 may exert a spin-orbit torque on second layer 112.

Moreover, when write current 108 flows through MTJ device 102, for example, through fourth layer 116 (e.g., a fixed layer of MTJ device 102), write current 108 may form a second or vertical component 108B of write current 108. Furthermore, second component 108B of write current 108 may also exert a torque on second layer 112. For example, second component 108B of write current 108 may exert a spin-transfer torque on second layer 112.

In these aspects, spin-transfer switching may be assisted by spin-orbit torque from spin Hall channel materials, for example, resulting in a decrease in the necessary switching current (e.g., a decrease of approximately 30%). Additionally, an operation voltage across a tunnel barrier (e.g., formed by third layer 114) may decrease, for example, by approximately 0.15 V. In some aspects, the reduced operation voltage may help to increase endurance cycles of MTJ device 102, for example, by approximately 200 times. Furthermore, in some aspects, there is no need of magnetic field for deterministic switching, for example, compared to convention spin-orbit torque devices. In a 1T1MTJ (e.g., one transistor and one MTJ device in one bit cell) two-terminal device, MRAM device 100 may include an increase in cell area of approximately 30%, which may be smaller than a 2T1MTJ (e.g., two transistors and one MTJ device in one bit cell) spin-orbit torque MRAM cell (e.g., which is 100% larger than a 1T1MTJ two-terminal device). Additionally, in some aspects, a length of thin spin Hall channel material may be minimized, for example, to help reduce Joule heating, as Joule heating may cause short endurance cycles (e.g., 1e⁹) in conventional spin-orbit torque MRAM devices.

MRAM device 100 may be formed in one or more manners or during one or more procedures. A first layer of spin Hall channel material (e.g., first layer 110) may be patterned with a free layer of a MTJ device (e.g., second layer 112), which may help to prevent degradation of the interface between the free layer and the spin Hall channel material. For example, the patterning may help to prevent degradation of the interface during the formation of the other spin Hall channel material (e.g., coupling layer 106). As mentioned, first layer 110 may have a higher resistivity than coupling layer 106 to help increase horizontal component 108A of write current 108. Additionally, coupling layer 106 may include a thickness (e.g., in the vertical direction of FIG. 1) of approximately 2 nm to approximately 8 nm, for example, approximately 4 nm to approximately 5 nm. First layer 110 may include a thickness (e.g., in the vertical direction of FIG. 1) of approximately 2 nm to approximately 6 nm, for example, approximately 3 nm. For example, first layer 110 may include a thickness that is less than (e.g., thinner than) a thickness of coupling layer 106.

In various aspects, coupling layer 106 and/or first layer 110 may be formed of one or more materials, for example, RuOx or Mn₃Sn, which may help to generate unconventional spin-orbit torque. For example, as mentioned above, one or more of coupling layer 106 or first layer 110 may be formed of spin Hall channel material. The generated unconventional spin-orbit torque may include a net perpendicular spin polarization. In some aspects, the generated unconventional spin-orbit torque may assist with spin torque transfer switching of perpendicular MTJ devices, for example, more strongly than conventional spin-orbit torque. Alternatively, or additionally, coupling layer 106 and/or first layer 110 may include one or more heavy metals, for example, such as β-W (beta-Tungsten), heavy metal alloys, or heavy metal multi-layers. In some aspects, coupling layer 106 and/or first layer 110 may include one or more topological insulators or transition metal dichalcogenides.

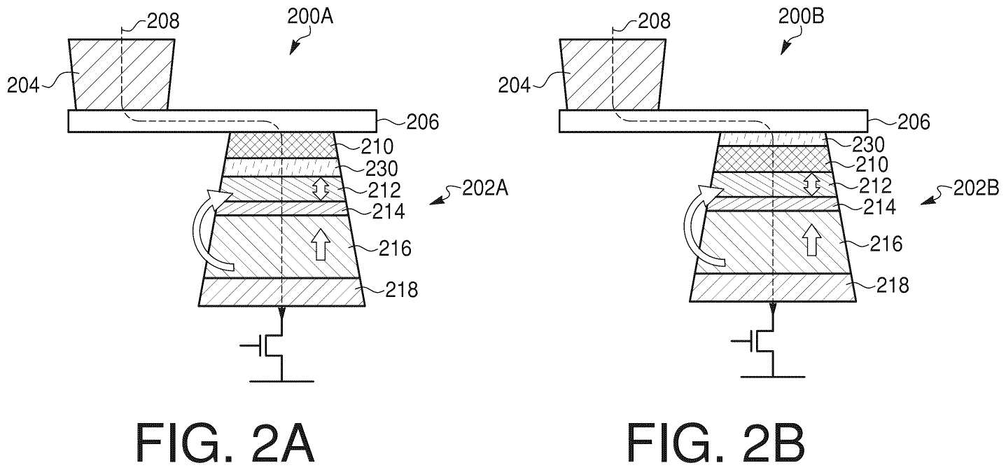

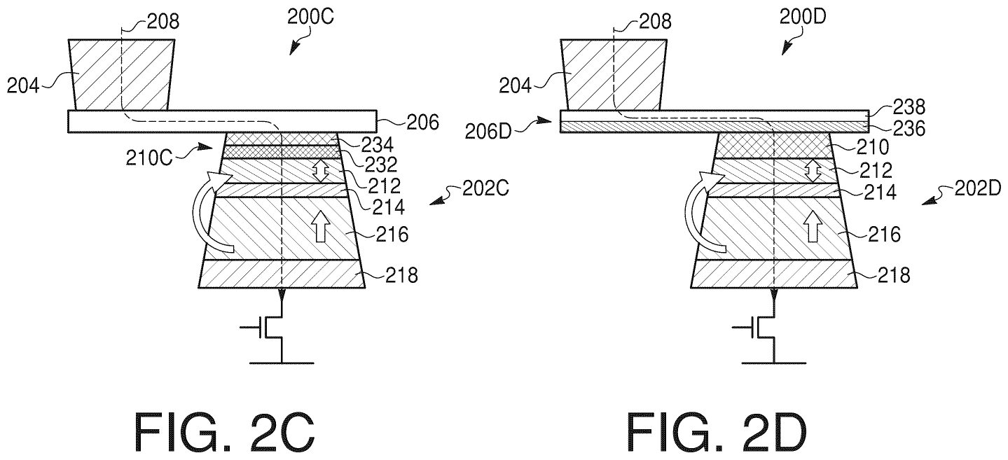

As shown in FIGS. 2A-2D, various MRAM devices 200A-200D may include one or more additional layers compared to MRAM device 100. As discussed above, MRAM devices 200A-200D include an electrode 204, spin Hall channel material forming a coupling layer 206, a spin Hall channel layer 210, and a MTJ device 200A-200D, each including a free layer 212, a tunnel barrier layer 214, a fixed layer 216, and a seed layer 218. MRAM devices 200A-200D may each receive a write current 208.

For example, as shown in FIG. 2A, one or more insulating layers 230 may be deposited, formed, or otherwise positioned between spin Hall channel layer 210 and free layer 212 of a MTJ device 202A. Insulating layer(s) 230 may be formed of MgO.

As shown in FIG. 2B, one or more insulating layers 230 may be deposited, formed, or otherwise positioned between spin Hall channel material of coupling layer 206 and spin Hall layer 210, for example, above or adjacent to a MTJ device 202B. Insulating layer(s) 230 may be formed of MgO.

As shown in FIG. 2C, spin Hall layer 210C may include two layers, for example, above or adjacent to a MTJ device 202C. For example, a first portion or layer 232 (e.g., a bottom portion or layer, for example, in contact with free layer 212) may include a higher resistivity than a second portion or layer 234 (e.g., a top portion of layer, for example, in contact with spin Hall material of coupling layer 206). In these aspects, first portion or layer 232 may include a higher resistivity than both second portion or layer 234 and coupling layer 206.

As shown in FIG. 2D, coupling layer 206D may include two layers. For example, a first portion or layer 236 (e.g., a bottom portion or layer, for example, in contact with spin Hall layer 210) may include a higher resistivity than a second portion or layer 238. In some aspects, first portion or layer 236 may include a higher resistivity than second portion or layer 238, but a lower resistivity than spin Hall layer 210, which may be above or adjacent to a MTJ device 202D. In some aspects, a portion of first portion or layer 236 is in contact with spin Hall layer 210 or MTJ device 202D. Furthermore, in some aspects, a portion of second portion or layer 238 is in contact with electrode 204.

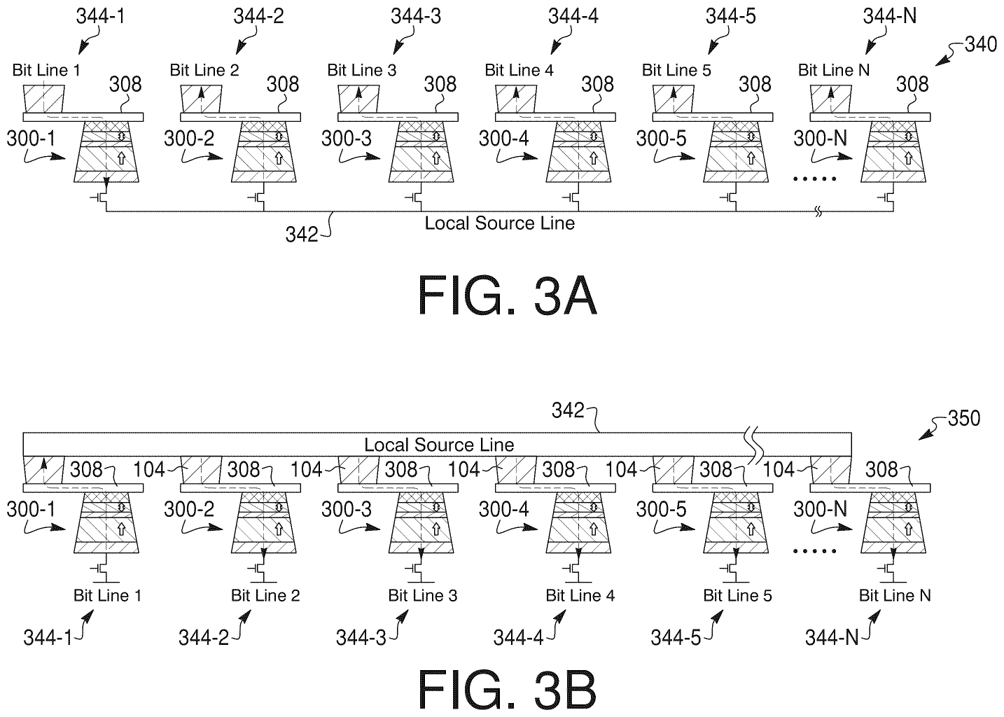

FIG. 3A illustrates an exemplary MRAM array 340, for example, including a plurality of MRAM devices 300-1, 300-2, 300-3, 300-4, 300-5, and 300-N, which each include a MTJ device 102, an electrode 104, and spin Hall channel material forming coupling layer 106, as discussed above. Additionally, although not shown, it is noted that MRAM devices 300-1, 300-2, 300-3, 300-4, 300-5, and 300-N may include other arrangements or components. For example, one or more of the MRAM devices may include one or more of MTJ devices (e.g., MTJ devices 202A, 202B, 202C, 202D) or the layers of material(s) discussed throughout this disclosure (e.g., insulating layer(s) 230 discussed with respect to FIGS. 2A and 2B, spin Hall layer 210C discussed with respect to FIG. 2C, coupling layer 206D discussed with respect to FIG. 2D, etc.).

In some aspects, MRAM array 340 may include any number of MRAM devices. In some aspects, MRAM array 340 may include 64 MRAM devices. In other aspects, MRAM array 340 may include 16 MRAM devices. Furthermore, in order to form an array system, MRAM array 340 may include or be coupled to at least one local source line 342 and a plurality of bit lines 344-1, 344-2, 344-3, 344-4, 344-5, and 344-N, for example, one bit line 344 for each MRAM device 100. As shown, write current 308 may flow from one bit line (e.g., first bit line 344-1), through one MRAM device (e.g., first MRAM device 300-1), and to local source line 342, for example, to write the one MRAM device (e.g., a write bit). Write current 308 may flow from local source line 342 through the other MRAM devices (e.g., MRAM devices 300-2, 300-3, 300-4, 300-5, and 300-N) to respective bit lines (e.g., bit lines 344-2, 344-3, 344-4, 344-5, and 344-N). In these aspects, MRAM array 340 may write one MRAM device at a time, and with the remainder of the MRAM devices (e.g., N-1 MRAM devices or bit cells) forming return paths for write current 308.

FIG. 3B illustrates another MRAM array 350, which may include a plurality of MRAM devices 300-1, 300-2, 300-3, 300-4, 300-5, and 300-N. The MRAM devices of MRAM array 350 may include or be coupled to local source line 342 and a plurality of bit lines 344-1, 344-2, 344-3, 344-4, 344-5, and 344-N, for example, to form an array system. MRAM array 350 may be similar to MRAM array 340, but the orientation of MRAM devices 300-1, 300-2, 300-3, 300-4, 300-5, and 300-N, local source line 342, and bit lines 344-1, 344-2, 344-3, 344-4, 344-5, and 344-N may be reversed compared to MRAM array 340. In these aspects, local source line 342 may be adjacent to the electrodes 104 of each MRAM device 300-1, 300-2, 300-3, 300-4, 300-5, and 300-N, and bit lines 344-1, 344-2, 344-3, 344-4, 344-5, and 344-N may be positioned on the opposing sides of MRAM devices 300-1, 300-2, 300-3, 300-4, 300-5, and 300-N. Nevertheless, as discussed above, write current 308 may flow from one bit line (e.g., first bit line 344-1), through one MRAM device (e.g., first MRAM device 300-1), and to local source line 342, for example, to write the one MRAM device (e.g., a write bit). Additionally, write current 308 may flow from local source line 342 through the other MRAM devices (e.g., MRAM devices 300-2, 300-3, 300-4, 300-5, and 300-N) to respective bit lines (e.g., bit lines 344-2, 344-3, 344-4, 344-5, and 344-N). In these aspects, MRAM array 350 may write one MRAM device at a time, and with the remainder of the MRAM devices (e.g., N-1 MRAM devices or bit cells) forming return paths for write current 308.

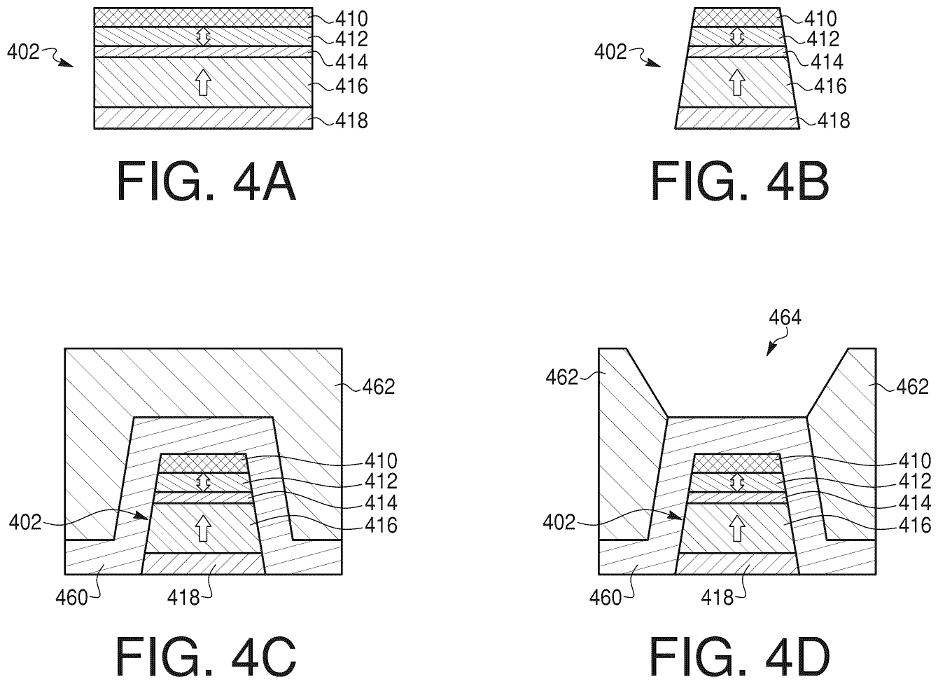

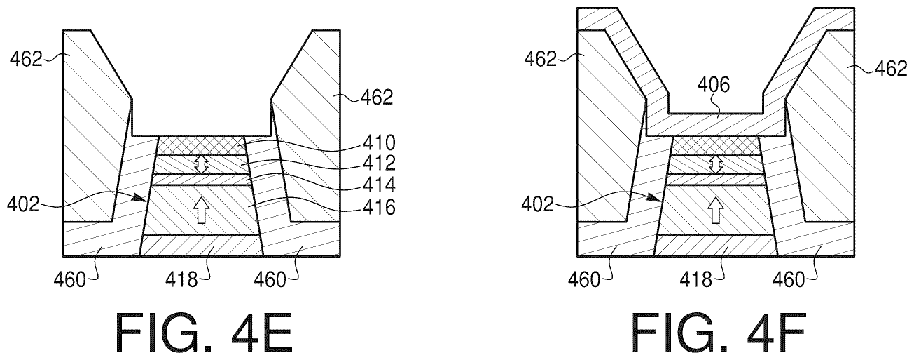

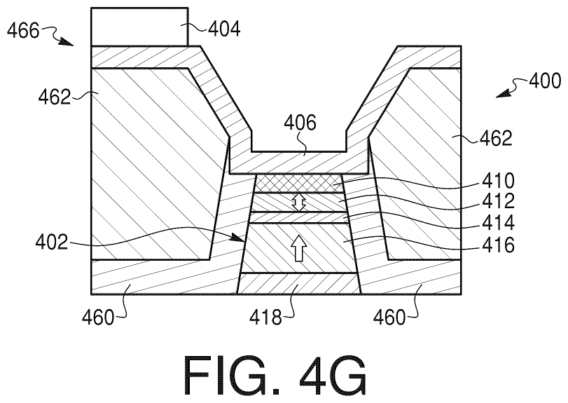

The MRAM devices and arrays discussed herein may be formed in various procedures. FIGS. 4A-4G illustrate aspects or stages of an exemplary fabrication process. As shown in FIG. 4A, in a first step, portions of a MTJ device 402 may be deposited, for example, including a free layer 412, a tunnel barrier layer 414, and a fixed layer 416. In some aspects, depositing portion of MTJ device 402 may also include depositing a seed layer 418. Additionally, as shown in FIG. 4A, the first step may also include depositing a first layer of spin Hall channel material (first SHC layer 410) over the MJT device 402. In some aspects, the first step may include patterning first SHC layer 410, for example, with free layer 412 to help prevent degradation of the interface between first SHC layer 410 and free layer 412. In some aspects, the patterning may help to prevent degradation of the interface between first SHC layer 410 and free layer 412 during the formation of a second layer of spin Hall channel material (e.g., above first SHC layer 410).

Next, a second step shown in FIG. 4B may include etching one or more portions of MTJ device 402 and first SHC layer 410. For example, as shown, the second step may include etching or otherwise shaping one or more of first SHC layer 410, free layer 412, tunnel barrier layer 414, fixed layer 416, or seed layer 418. In some aspects, the etching may form a trapezoidal shape, for example, with seed layer 418 being wider than first SHC layer 410.

Then, a third step shown in FIG. 4C may include depositing one or more materials, for example, over MTJ device 402 and first SHC layer 410. For example, the third step may include depositing two materials over MTJ device 402 and first SHC layer 410. In some aspects, a first material 460 may be SiN, and a second material 462 may be SiO₂ made from tetraethoxysilane (TEOS). First material 460 may be deposited over MTJ device 402 and first SHC layer 410, and second material 462 may be deposited over first material 460.

Next, a fourth step shown in FIG. 4D may include etching one more vias 464. As shown, the etching may include etching one or more vias 464 through second material 462. The etching may stop at first material 460. Alternatively, in some aspects, a portion of first material 460 may be removed, with another portion of first portion 460 remaining above or adjacent to MTJ device 402.

Furthermore, a fifth step shown in FIG. 4E may include etching (e.g., controlled etching) of first material 460 (or second material 462). As shown, the etching in the fifth step shown in FIG. 4E may stop at first SHC layer 410. Alternatively, in some aspects, a portion of first SHC layer 410 may be removed, with another portion of first SHC layer 410 remaining above or adjacent to MTJ device 402. In some aspects, one or more portions of first SHC layer 410 may include or be at least partially formed of β-W (e.g., beta-Tungsten), which may help to control the etching process or otherwise stop the etching at first SHC layer 410.

Then, a sixth step shown in FIG. 4F may include depositing spin Hall channel material, for example, to form a second SHC layer 406. As shown, second SHC layer 406 may be deposited above or otherwise adjacent to (e.g., in abutting contact) with first SHC layer 410. Second SHC layer 406 may also extend beyond MTJ device 402, for example, in at least one direction (e.g., left or right, as shown in FIG. 4F) relative to MTJ device 402. For example, second SHC layer 406 may be positioned above or otherwise adjacent to first material 460 or second material 462.

Additionally, a seventh step shown in FIG. 4G may include patterning of one or more portions of second SHC layer 406, for example, to form a contact 466 to couple an electrode 404 to second SHC layer 406. As discussed above, FIG. 4G illustrates electrode 404 being electrically coupled to MTJ device 402 (e.g., via second SHC layer 406 and first SHC layer 410), for example, forming a MRAM device 400. Additionally, as discussed above, a write current (not shown) may be transmitted from electrode 404 and through second and first SHC layers 406, 410 to MTJ device 402. Furthermore, as discussed above, the write current may have both a horizontal component and a vertical component, which may help to write or otherwise program one or more aspects of MTJ device 402. Moreover, the various formation steps (e.g., depositing, etching, patterning, etc.) may help to preserve the interface between first SHC layer 410 and free layer 412, for example, in a same condition as the layers were initially deposited or otherwise formed.

As mentioned above, various aspects of this disclosure may help to improve one or more aspects of an operation or write current. The spacing between the electrode and the MTJ device may increase a cell area (e.g., by approximately 30%) compared to STT-MRAM devices. Nevertheless, because the operation or write current is reduced, the overall MTJ device or array of MTJ devices may be smaller, for example, helping to maintain an overall similar cell area as STT-MRAM devices. As discussed above, various aspects of this disclosure may also help to improve or lengthen an endurance cycle or operational lifetime of MTJ devices or arrays of MTJ devices. For example, various aspects of this disclosure may help to provide for MRAM devices with STT switching assisted by SOT switching.

In some aspects, various features of this disclosure may help to provide for temperature dependence (e.g., between approximately −40° C. and approximately 125° C.). For example, the resistance or resistivity of the higher resistivity of the first SHC layer (e.g., first, spin Hall, and first SHC layer 110, 210, 410) relative to the second SHC layer (e.g., layers 106, 206, 406) may decrease with increasing temperature. This temperature dependence may be within one or more temperature ranges, for example, between approximately −40° C. and approximately 125° C. Similarly, in embodiments where the MTJ device includes one or more insulator layers (e.g., insulating layer(s) 230), the resistance of the insulator layer(s) may also decrease with increasing temperature. Similarly, in embodiments where the spin Hall layer 210C may include two layers, the resistance or resistivity of the first portion or layer 232 (e.g., a bottom portion or layer, for example, in contact with free layer 212) may also decrease with increasing temperature. Similarly, in embodiments where the coupling layer 206D may include two layers, the resistance or resistivity of the first portion or layer 236 (e.g., a bottom portion or layer, for example, in contact with spin Hall layer 210) may also decrease with increasing temperature. In some aspects, the resistance of tunnel barrier layers 114, 214 may also decrease with increasing temperature. In these aspects, if the resistance or resistivity of these layers is higher, then the horizontal component of the write current may be stronger, resulting in spin-orbit torque (SOT) being stronger. Across the above-mentioned temperature range, at lower temperatures, SOT assist effect may be stronger, which may help to relax the temperature dependence of the required current in conventional STT. Nevertheless, by adjusting a temperature dependence of resistance(s) or resistivity(ies), it may be possible to tune a temperature dependence of switching current of the MTJ, which may help to provide a balance between switching current of the MTJ and a supply of a current from a circuit (e.g., a write current from a write circuit).

Additionally, within a write pulse, the effects of SOT and STT may vary. In these aspects, during a write pulse, the resistance or resistivity of the aforementioned layers decreases with time due to Joule heating by the write current (e.g., write current 108, 208, 308). For example, at a beginning of a write pulse, the SOT effect may be the strongest, and the SOT effect may gradually decrease as the MTJ temperature increases. Furthermore, when STT switching is assisted by SOT, as discussed above, it may be desirable to have the strongest SOT effect at the beginning of the write pulse and the weakest SOT effect at a middle or end of the write pulse. For example, these effects may help to reduce switching current. For example, SOT effect at the beginning of the write pulse may help to immediately or effectively start a rotation of the magnetization of the free layer (e.g., layer(s) 112, 212, 412), while STT may require an incubation delay in timing to start the rotation of the magnetization. Additionally, a strong SOT effect at the middle or end of the write pulse may hinder the magnetization of the free layer from completing the switching. For example, the direction of SOT may not be exactly the same as the final magnetization direction or state.

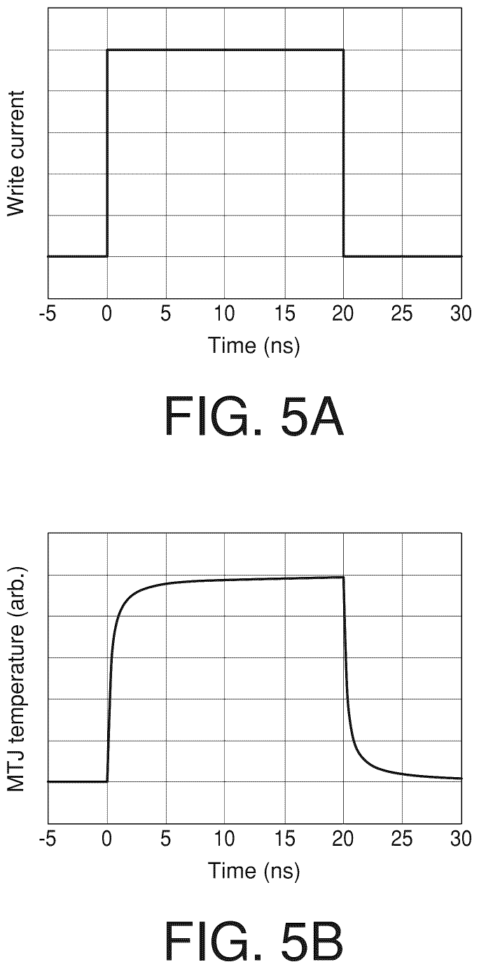

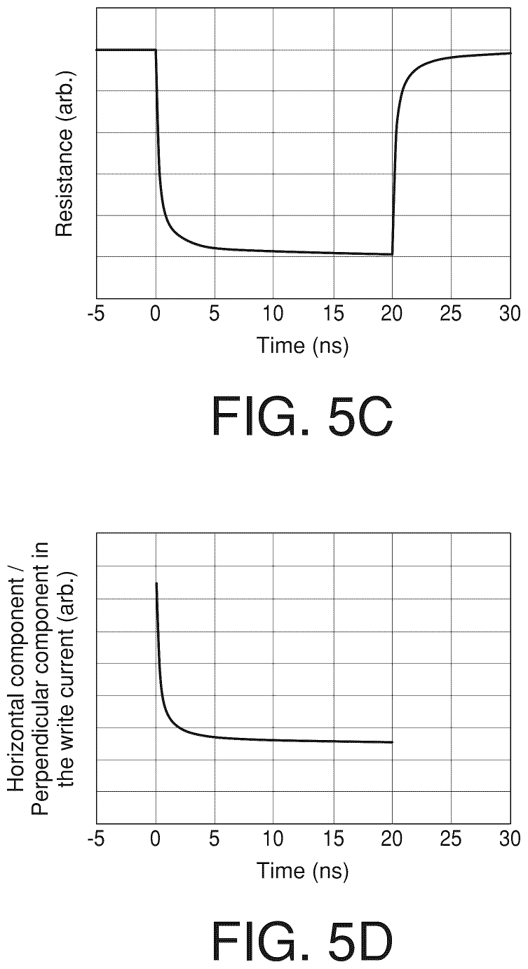

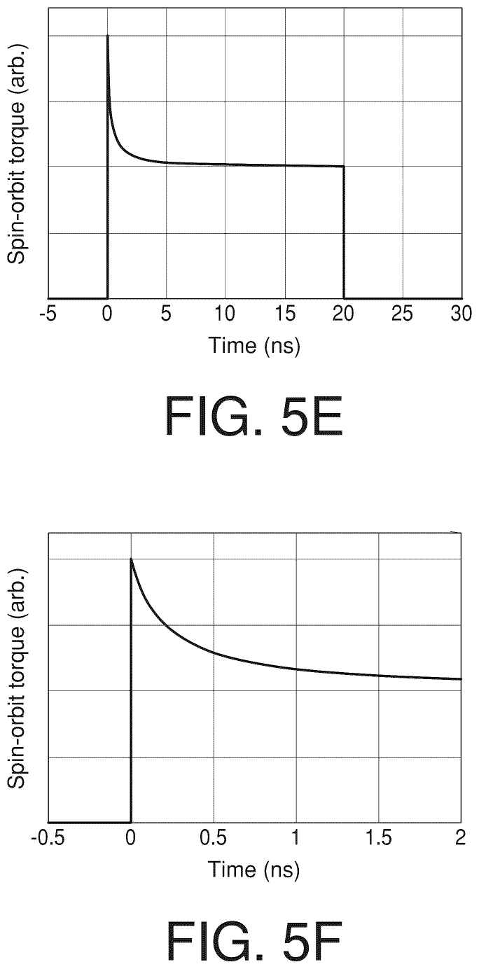

For instance, FIGS. 5A-5E illustrate graphs of various aspects of exemplary MRAM devices and responses during a write pulse. For example, a write pulse may include a width or duration of approximately 20 nanoseconds. In this example, FIG. 5A illustrates a write current (y-axis) over time (x-axis), with the write pulse width being approximately 20 nanoseconds. FIG. 5B illustrates a MTJ temperature (y-axis) over time (x-axis). FIG. 5C illustrates a resistance (y-axis) over time (x-axis). FIG. 5D illustrates the ratio of a horizontal component over a perpendicular component of the write current (y-axis) over time (x-axis). FIG. 5E illustrates a spin-orbit torque (y-axis) over time (x-axis). FIG. 5F illustrates an enlarged portion of FIG. 5E, a spin-orbit torque (y-axis) over time (x-axis). For example, FIG. 5F illustrates that, during the first approximately 0.2 nanoseconds to approximately 1.0 nanoseconds, spin-orbit torque is high, which may help to reduce the switching current.

Various aspects of this disclosure may help to improve the reliability of the resulting MRAM devices, without significantly increasing the costs of formation (e.g., various deposition or etching processes discussed above may increase costs or formation time). Various aspects of this disclosure may be useful for industrial, aerospace, military, or other applications or uses.

In the embodiments discussed above, one or more of MRAM devices 100, 200A-200D, 300-1 to 300-N, 400 may be a standalone chip. Alternatively, MRAM devices 100, 200, 300, 400 may be a die in a multi-chip package (MCP). Furthermore, in other aspects, MRAM devices 100, 200, 300, 400 may be a part of a system-in-a-package (SiP). In any of these aspects, MRAM devices 100, 200, 300, 400 each include various circuit blocks. Additionally, MRAM devices 100, 200, 300, 400 each include one or more interface blocks with IOs for external communication. The interface block(s) can be xSPI, parallel, serial, double data rate (DDR), or other types of interfaces. Moreover, although not shown, MRAM devices 100, 200, 300, 400 may include banks (e.g., memory array banks), and the banks may be chiplet-like wide IO data fetch. For example, the banks in MRAM devices 100, 200, 300, 400 may be 1024 or 512 bit data wide input/output in ST-DDR (spin-torque double data rate). In other aspects, the banks in MRAM devices 100, 200, 300, 400 may be 256 or less bit data wide input/output in xSPI STT-MRAM (expanded serial peripheral interface spin-transfer-torque MRAM).\

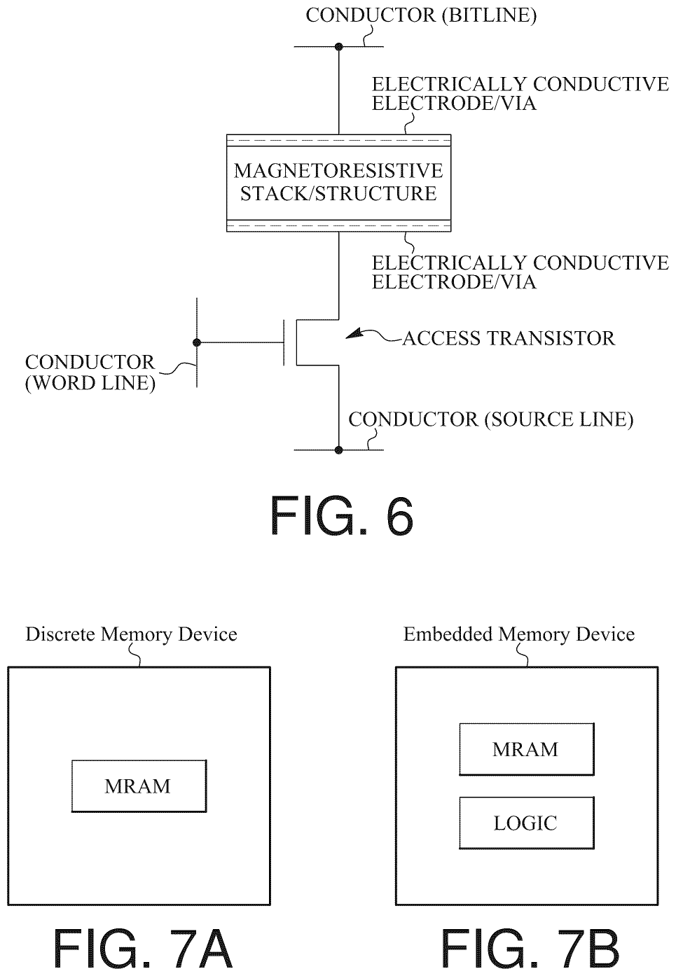

As alluded to above, the magnetoresistive devices (formed using aforementioned described techniques and/or processes) may include a sensor architecture or a memory architecture (among other architectures). For example, in a magnetoresistive device having a memory configuration, the magnetoresistive devices may be electrically connected to an access transistor and configured to couple or connect to various conductors, which may carry one or more control signals, as shown in FIG. 6. The magnetoresistive devices may be used in any suitable application, including, for example, in a memory configuration. In such instances, the magnetoresistive devices may be formed as an IC device comprising a discrete memory device (e.g., as shown in FIG. 7A) or an embedded memory device having a logic therein (e.g., as shown in FIG. 7B), each including MRAM, which, in one embodiment is representative of one or more arrays of MRAM having a plurality of magnetoresistive devices formed magnetoresistive stacks/structures, according to certain aspects of certain embodiments disclosed herein.

The devices and structures disclosed herein may be used alone or in combination with one or more features disclosed in the following patents: U.S. Pat. No. 9,336,872; U.S. Pat. No. 9,754,652; U.S. Pat. No. 9,336,849; U.S. Pat. No. 9,530,476; and U.S. Pat. No. 9,697,879, the entireties of which are incorporated by reference herein.

There are many embodiments of the present disclosure described and illustrated herein. The present disclosure is neither limited to any single aspect nor embodiment thereof, nor to any combinations and/or permutations of such aspects and/or embodiments. Moreover, each of the aspects of the present disclosure, and/or embodiments thereof, may be employed alone or in combination with one or more of the other aspects of the present disclosure and/or embodiments thereof. For the sake of brevity, certain permutations and combinations are not discussed and/or illustrated separately herein; however, all permutations and combinations are considered to fall within the scope of the present inventions.

In one embodiment, a magnetoresistive random-access memory (MRAM) device may include a magnetoresistive tunnel junction (MTJ) device, an electrode, and a coupling layer. The MTJ device may include a free layer, a fixed layer, and a tunnel barrier layer positioned between the free layer and the fixed layer. The coupling layer may be positioned between and coupling the electrode and the MTJ device. The coupling layer may include spin Hall channel (SHC) material. The free layer, the fixed layer, and the tunnel barrier layer may be stacked in a first direction to form MTJ device. The electrode may be nonaligned with the MTJ device such that the electrode is spaced away from the MTJ in a second direction that is different from the first direction.

In various embodiments, the MRAM device may include one or more of the following aspects. The MRAM device may further include a layer of spin Hall channel (SHC) material positioned between the coupling layer and the MTJ device. The MRAM device may further include a layer of spin Hall channel (SHC) material positioned between the coupling layer and the MTJ device, and the layer of SHC material may have a higher resistivity than the coupling layer. The MRAM device may further include a layer of spin Hall channel (SHC) material positioned between the coupling layers and the MTJ device, the layer of SHC material may have a higher resistivity than the coupling layer, and the resistivity of the layer of SHC material may decrease with increasing temperature. The MRAM device may further include a layer of spin Hall channel (SHC) material positioned between the coupling layer and the MTJ device, and one or more insulating layers positioned between the coupling layer and the layer of SHC material. The MRAM device may further include a layer of spin Hall channel (SHC) material positioned between the coupling layer and the MTJ device, and one or more insulating layers positioned between the layer of SHC material and the free layer of the MTJ device. The MRAM device may further include a layer of spin Hall channel (SHC) material positioned between the coupling layer and the MTJ device. The layer of SHC material may include a bottom layer and a top layer. The bottom layer may be in contact with the free layer of the MTJ device. The top layer may be in contact with the coupling layer, and the bottom layer may include a higher resistivity than the top layer. The resistivity of the bottom layer may decrease with increasing temperature. The coupling layer may include a first layer and a second layer, and the first layer may include a higher resistivity than the second layer. The second layer may be in contact with the electrode. The resistivity of the first layer of the coupling layer may decrease with increasing temperature. The electrode may be configured to be coupled to a bit line, and the MTJ device may be configured to be coupled to a local source line. The electrode may be configured to be coupled to a local source line, and the MTJ device may be configured to be coupled to a bit line. The MRAM device may include a vertical axis and a horizontal axis, and the electrode may be spaced away from the MTJ device in a direction along the horizontal axis by a distance that is approximately twice of a thickness of the coupling layer. The electrode may be an electrode via that may be configured to receive a write current to be transmitted through the electrode via, the coupling layer, and the MTJ device. The MRAM device may further include a seed layer, and the seed layer may be positioned adjacent to the fixed layer.

In another embodiment, a magnetoresistive random-access memory (MRAM) device may include a magnetoresistive tunnel junction (MTJ) device, an electrode, a coupling layer positioned between and coupling the electrode and the MTJ device, and a layer of spin Hall channel (SHC) material positioned between the coupling layer and the MTJ device. The MTJ device may include a free layer, a fixed layer, and a tunnel barrier layer positioned between the free layer and the fixed layer. The electrode may be nonaligned with the MTJ device.

In various embodiments, the MRAM device may include one or more of the following aspects. The coupling layer may include spin Hall channel material. The MRAM device may include a vertical axis and a horizontal axis. The electrode may be spaced away from the MTJ device in a direction along the horizontal axis by a distance that is approximately twice of a thickness of the coupling layer. The electrode may be an electrode via, which may be configured to receive a write current to be transmitted through the electrode via, the coupling layer, the layer of SHC material, and the MTJ device. The layer of SHC material may have a higher resistivity than the coupling layer. The resistivity of the layer of SHC material may decrease with increasing temperature. The MRAM device may further include one or more insulating layers positioned between the coupling layer and the layer of SHC material.

In yet another embodiment, a magnetoresistive random-access memory (MRAM) device array system may include a plurality of MRAM devices, a source line electrically coupled to each of the MRAM devices, and a plurality of bit lines. Each MRAM device may include a magnetoresistive tunnel junction (MTJ) device, an electrode, and a coupling layer positioned between and coupling the electrode and the MTJ device. The MTJ device may include a free layer, a fixed layer, and a tunnel barrier layer positioned between the free layer and the fixed layer. The electrode may be nonaligned with the MTJ device. The coupling layer may include spin Hall channel material. Each bit line may be electrically coupled to one of the plurality of MRAM devices.

In various embodiments, the MRAM device array system may include one or more of the following aspects. The electrode of the MTJ device of each of the plurality of MRAM devices may be coupled to a respective bit line, and the MTJ devices may each be coupled to the source line. The electrode of the MTJ device of each of the plurality of MRAM devices may be coupled to the source line, and the MTJ devices may each be coupled to a respective bit line.

The foregoing description of the inventions has been described for purposes of clarity and understanding. It is not intended to limit the inventions to the precise form disclosed. Various modifications may be possible within the scope and equivalence of the application.

We claim:

1. A magnetoresistive random-access memory (MRAM) device, the MRAM device comprising:
a magnetoresistive tunnel junction (MTJ) device, wherein the MTJ device includes:
a free layer;
a fixed layer; and
a tunnel barrier layer positioned between the free layer and the fixed layer;
an electrode; and
a coupling layer positioned between and coupling the electrode and the MTJ device, wherein the coupling layer includes spin Hall channel (SHC) material,
wherein the free layer, the fixed layer, and the tunnel barrier layer are stacked in a first direction to form MTJ device, wherein the electrode is nonaligned with the MTJ device such that the electrode is spaced away from the MTJ in a second direction that is different from the first direction.

2. The MRAM device of claim 1, further comprising a layer of spin Hall channel (SHC) material positioned between the coupling layer and the MTJ device.

3. The MRAM device of claim 1, further comprising a layer of spin Hall channel (SHC) material positioned between the coupling layer and the MTJ device, wherein the layer of SHC material has a higher resistivity than the coupling layer.

4. The MRAM device of claim 1, further comprising a layer of spin Hall channel (SHC) material positioned between the coupling layer and the MTJ device, wherein the layer of SHC material has a higher resistivity than the coupling layer, and wherein the resistivity of the layer of SHC material decreases with increasing temperature.

5. The MRAM device of claim 1, further comprising:
a layer of spin Hall channel (SHC) material positioned between the coupling layer and the MTJ device; and
one or more insulating layers positioned between the coupling layer and the layer of SHC material.

6. The MRAM device of claim 1, further comprising:
a layer of spin Hall channel (SHC) material positioned between the coupling layer and the MTJ device; and
one or more insulating layers positioned between the layer of SHC material and the free layer of the MTJ device.

7. The MRAM device of claim 1, further comprising a layer of spin Hall channel (SHC) material positioned between the coupling layer and the MTJ device, wherein the layer of SHC material includes a bottom layer and a top layer, wherein the bottom layer is in contact with the free layer of the MTJ device, wherein the top layer is in contact with the coupling layer, wherein the bottom layer includes a higher resistivity than the top layer, and wherein the resistivity of the bottom layer decreases with increasing temperature.

8. The MRAM device of claim 1, wherein the coupling layer includes a first layer and a second layer, wherein the first layer includes a higher resistivity than the second layer, and wherein the second layer is in contact with the electrode.

9. The MRAM device of claim 1, wherein the coupling layer includes a first layer and a second layer, wherein the first layer includes a higher resistivity than the second layer, wherein the second layer is in contact with the electrode, and wherein the resistivity of the first layer of the coupling layer decreases with increasing temperature.

10. The MRAM device of claim 1, wherein (1) the electrode is configured to be coupled to a bit line, and the MTJ device is configured to be coupled to a local source line; or (2) the electrode is configured to be coupled to a local source line, and the MTJ device is configured to be coupled to a bit line.

11. The MRAM device of claim 1, wherein the MRAM device includes a vertical axis and a horizontal axis, and wherein the electrode is spaced away from the MTJ device in a direction along the horizontal axis by a distance that is approximately twice of a thickness of the coupling layer.

12. The MRAM device of claim 1, further comprising a seed layer, wherein the seed layer is positioned adjacent to the fixed layer, and wherein the electrode is an electrode via configured to receive a write current to be transmitted through the electrode via, the coupling layer, and the MTJ device.

13. A magnetoresistive random-access memory (MRAM) device, the MRAM device comprising:
a magnetoresistive tunnel junction (MTJ) device, wherein the MTJ device includes:
a free layer;
a fixed layer; and
a tunnel barrier layer positioned between the free layer and the fixed layer;
an electrode;
a coupling layer positioned between and coupling the electrode and the MTJ device; and
a layer of spin Hall channel (SHC) material positioned between the coupling layer and the MTJ device,
wherein the electrode is nonaligned with the MTJ device.

14. The MRAM device of claim 13, wherein the coupling layer includes spin Hall channel (SHC) material, wherein the MRAM device includes a vertical axis and a horizontal axis, and wherein the electrode is spaced away from the MTJ device in a direction along the horizontal axis by a distance that is approximately twice of a thickness of the coupling layer.

15. The MRAM device of claim 13, wherein the electrode is an electrode via configured to receive a write current to be transmitted through the electrode via, the coupling layer, the layer of SHC material, and the MTJ device.

16. The MRAM device of claim 13, wherein the layer of SHC material has a higher resistivity than the coupling layer, and wherein the resistivity of the layer of SHC material decreases with increasing temperature.

17. The MRAM device of claim 13, further comprising one or more insulating layers positioned between the coupling layer and the layer of SHC material.

18. A magnetoresistive random-access memory (MRAM) device array system, the MRAM device array comprising:
a plurality of MRAM devices, each MRAM device comprising:
a magnetoresistive tunnel junction (MTJ) device, wherein the MTJ device includes:
a free layer;
a fixed layer; and
a tunnel barrier layer positioned between the free layer and the fixed layer;
an electrode, wherein the electrode is nonaligned with the MTJ device; and
a coupling layer positioned between and coupling the electrode and the MTJ device, wherein the coupling layer includes spin Hall channel material;
a source line electrically coupled to each of the MRAM devices; and
a plurality of bit lines, each bit line being electrically coupled to one of the plurality of MRAM devices.

19. The MRAM device array system of claim 18, wherein the electrode of the MTJ device of each of the plurality of MRAM devices is coupled to a respective bit line, and wherein the MTJ devices are each coupled to the source line.

20. The MRAM device array system of claim 18, wherein the electrode of the MTJ device of each of the plurality of MRAM devices is coupled to the source line, and wherein the MTJ devices are each coupled to a respective bit line.
